(19) United States
(12) Patent Application Publication
(10) Pub. No.: US 2017/0046224 A1
(43) Pub. Date: Feb. 16, 2017

(54) STORING DATA IN STORAGE DEVICES

(71) Applicant: EMPIRE TECHNOLOGY DEVELOPMENT LLC, Wilmington, DE (US)

(72) Inventor: Hyoung-GON LEE, Gapyeong-gun (KR)

(73) Assignee: EMPIRE TECHNOLOGY DEVELOPMENT LLC, Wilmington, DE (US)

(21) Appl. No.: 15/305,659

(22) PCT Filed: Apr. 25, 2014
(86) PCT No.: PCT/US14/35380

§ 371 Date: Oct. 21, 2016

(51) Int. Cl. G06F 11/10; G06F 3/06; H03M 13/15; G11C 7/00; G11C 29/52

(52) U.S. Cl. CPC G06F 11/1068; G11C 7/00; G11C 29/52; H03M 13/1515; H03M 13/152; G06F 3/061; G06F 3/0619; G06F 3/064; G06F 3/0655; G06F 3/0673

(57) ABSTRACT

Technologies are generally described to store data in a storage device that includes an array of analog memory cells. Example storage devices described herein may include one or more of an interface, and/or a processor coupled to the interface. The processor may be configured to store, via the interface, data as first analog values in a first group of memory cells in the array. Second analog values may be read, via the interface, from the first group of memory cells in which the data were stored. A first distortion representative of a difference between the first analog values and the second analog values may be then verified. Further, the second analog values may be encoded by use of an error correction code (ECC) to generate third analog values. The third analog values may be stored, via the interface, in a second group of memory cells in the array.

### BACKGROUND

Unless otherwise indicated herein, the approaches described in this section are not prior art to the claims in this application and are not admitted to be prior art by inclusion in this section.

Several types of memory devices, such as flash memories and dynamic random access memories (DRAMs), may use arrays of analog memory cells for storing data. In such memory devices, each analog memory cell may typically include a transistor, which holds a certain amount of electric charge that represents information stored in the cell. The electric charge written into a particular memory cell may affect the threshold voltage of the cell, e.g., the voltage to be applied to the cell so that the cell will conduct current. However, the threshold voltage values read from analog memory cells may sometimes be distorted due to various reasons, such as electrical field coupling from neighboring memory cells, back pattern dependency (BPD) caused by other cells along the same column of the array, disturb noise caused by operations on other cells in the array, threshold voltage drift caused by device aging, and/or other reasons.

Flash memory based storage devices including solid state drives (SSDs) may use an error correction code (ECC) to store data in a stable manner. In one example method of storing data using an ECC in SSDs, original user data may be encoded using the ECC to generate a parity and then an encoded codeword may be created by attaching the parity to the original user data. After programming the encoded codeword in memory cells, the programmed data may be verified by comparing threshold voltages of the programmed cells with reference voltage values.

In some conventional methods of storing data using an ECC, where the ECC parity may be generated based on the original user data and programmed along with the user data, it may be difficult to measure an actual error occurring in data reading operations and reflect such error in generating encoded codewords. As a result, the encoded codewords may be vulnerable to errors occurring in performing read/write/erase operations thereon.

### SUMMARY

Technologies are generally described to store data by use of an error correction code in storage devices.

Various example storage devices described herein may include one or more of an interface, and/or a processor coupled to the interface. The processor may be configured to perform or cause to be performed: store, via the interface, data as first analog values in a first group of memory cells in the array; read, via the interface, second analog values from the first group of memory cells in which the data were stored; verify a first distortion representative of a difference between the first analog values and the second analog values; encode the second analog values by use of an error correction code (ECC) to generate third analog values; and store, via the interface, the third analog values in a second group of memory cells in the array.

In some examples, methods to store data in a storage device that includes an array of analog memory cells are described. Example methods may include storing data as first analog values in a first group of memory cells in the array. Second analog values may be read from the first group of memory cells in which the data were stored. A first distortion representative of a difference between the first analog values and the second analog values may be verified. Further, the second analog values may be encoded using an ECC to generate third analog values. The third analog values may be stored in a second group of memory cells in the array.

In some examples, a computer-readable storage medium is described that may be adapted to store a program operable by a storage device to store data in an array of analog memory cells. The processor may include various features as further described herein. The program may include one or more instructions to store data as first analog values in a first group of memory cells in the array, and reading second analog values from the first group of memory cells in which the data were stored. The program may further include one or more instructions to verify a first distortion representative of a difference between the first analog values and the second analog values, encode the second analog values using an ECC to generate third analog values, and store the third analog values in a second group of memory cells in the array.

In some examples, storage devices are described. Example devices may include one or more of a first interface, a second interface, and/or a processor coupled to the first and second interfaces. The first interface may be configured to communicate with a first array of analog memory cells, and the second interface may be configured to communication with a second array of analog memory cells. The processor may be configured to perform or cause to be performed: store, via the first interface, first data as first analog values in a first group of memory cells in the first array; read, via the first interface, second analog values from the first group of memory cells in which the first data were stored; verify a first distortion representative of a difference between the first analog values and the second analog values; encode the second analog values by use of an ECC to generate third analog values; and store, via the first interface, the third analog values in a second group of memory cells in the first array. The processor may be further configured to perform or cause to be performed: store, via the second interface, second data as other analog values in a group of memory cells in the second array during at least one of the read of the second analog values, the verification of the first distortion, the encode of the second analog values, and the storage of the third analog values to carry out a pipeline program operation upon the first and second arrays of analog memory cells.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 shows a block diagram of an illustrative example storage device including an array of memory cells;

FIG. 2 shows an illustrative example operation flow to program data in a storage device using an ECC encoding method;

FIG. 3 shows an illustrative example array of memory cells where an encoded codeword including user data and parity values may be stored;

FIG. 4 shows a block diagram of an illustrative example storage device including a plurality of arrays of memory cells;

FIG. 5 shows a timing graph of an illustrative example pipeline operation to program data in a plurality of arrays of memory cells;

FIG. 6 shows a timing graph of another illustrative example pipeline operation to program data in a plurality of pages in an array of memory cells;

FIG. 7 shows another illustrative example array of memory cells where an encoded codeword including user data and parity data may be stored;

FIG. 8 shows yet another illustrative example array of memory cells where an encoded codeword including user data and parity data may be stored;

FIG. 9 illustrates an example flow diagram of a method adapted to store data in a storage device that includes an array of memory cells;

FIG. 10 shows a block diagram of an example computing system that can be configured to implement methods to store data in a storage device that includes an array of memory cells; and

FIG. 11 illustrates a computer program product that can be utilized to store data in a storage device that includes an array of memory cells,

all arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. The aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to methods, apparatus, systems, devices and computer program products related to storing data in a storage device.

Briefly stated, technologies are generally described for storing data in a storage device that includes one or more arrays of analog memory cells. Example storage devices described herein may include one or more interfaces, and/or a processor coupled to the interfaces. The processor may be configured to store or otherwise control storage of, via a first interface among the one or more interfaces, first data as first analog values in a first group of memory cells in a first array of analog memory cells among the one or more arrays of analog memory cells. Second analog values may be read, via the first interface, from the first group of memory cells in which the first data were stored. A first distortion representative of a difference between the first analog values and the second analog values may be then verified. Further, the second analog values may be encoded by use of an error correction code (ECC) to generate third analog values. The third analog values may be stored, via the first interface, in a second group of memory cells in the first array.

In some embodiments, the processor may be further configured to perform storing or control storage of, via a second interface among the one or more interfaces, second data as other analog values in a group of memory cells in the second array of analog memory cells among the one or more arrays of analog memory cells during at least one of the operation of reading the second analog values, the operation of verifying the first distortion, the operation of encoding the second analog values and the operation of storing the third analog values to carry out a pipeline programming operation upon the first and second arrays of analog memory cells.

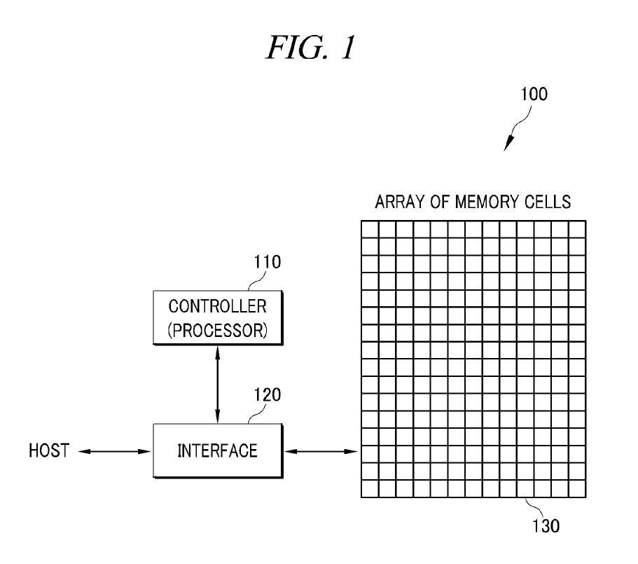

FIG. 1 shows a block diagram of an illustrative example storage device including an array of memory cells, arranged in accordance with at least some embodiments described herein. As depicted, a storage device 100 may include one or more of a controller 110, an interface 120, and/or an array 130 of memory cells coupled to each other. Interface 120 may operate under control/instructions of controller 110 to transfer data between array 130 and a host device (not shown). In some embodiments, array 130 of memory cells may include any suitable type of memory device, such as a flash memory device or a solid-state drive (SSD), including an array of nonvolatile analog memory cells. As used herein, the term “analog memory cell” may refer to any memory cell that stores information by holding a continuous, analog value of a physical parameter, such as an electrical voltage or charge. Array 130 may include any type of analog memory cells, such as NAND or NOR flash cells, phase change memory (PCM), nitride read-only memory (NROM), ferroelectric random access memory (FRAM), magnetoresistive RAM (MRAM), dynamic RAM (DRAM), and/or other type of memory cells. Also, controller 110 may include any suitable type of processor unit such as a programmable microcontroller, multicore processor, central processing unit (CPU), or others.

In some embodiments, memory cells in array 130 may be arranged in a grid having multiple rows and columns. A unit data value (e.g., a binary value or analog continuous value) may be stored in a particular cell by applying appropriate voltage levels or a certain amount of electrical charge to each cell of array 130. The value stored in each cell may be read by measuring the threshold voltage of the cell. In some embodiments, controller 110 may read an entire row of cells, which may also be referred to as a page, simultaneously.

The voltages read by controller 110 may contain various types of distortion, which may be caused by different distortion mechanisms in array 130. For example, electrical coupling between adjacent cells in the array may modify the threshold voltage in a particular cell, which is referred to as interference noise. Another example of distortion may include an aging effect by which electrical charge may leak from the cells over time and thus the threshold voltage of the cells may drift over time from the initially-written value. Yet another type of distortion, referred to as disturb noise, may be caused by read/write/erase operations on a certain cell in the array, which may cause unintended programming or erasure of other cells. These distortions may cause an erroneous reading of the data content of the cells.

In some embodiments, storage device 100 may reduce the probability of making erroneous decisions as to the data content of memory cells in array 130 by encoding measured threshold voltages and/or a distortion that may occur in storing data in the cells using an ECC. Various types of error correcting codes may be used to encode measured threshold voltages and/or a distortion. For example, the ECC may include a block code that separately encodes fixed-size blocks of data, including but not limited to the Bose-Chaudhuri-Hochquenghem (BCH) code or the Reed-Solomon (RS) code as examples.

In operation, controller 110 may be configured to communicate with array 130 of memory cells via interface 120. Controller 110 may receive user data from the host computer and store or program the user data in a group of memory cells (e.g., a first portion of a page) in array 130. Then, controller 110 may verify the stored user data by determining whether a distortion occurring in programming the user data (or program error) is within a predetermined tolerance. If the program error is less than the tolerance, controller 110 may encode measured threshold voltages and/or the distortion, e.g., by generating parity values based on measured threshold voltages and/or the distortion. The encoded data may be stored in another group of memory cells (e.g., a second portion of the page) along with the user data. The encoded data may be verified to determine whether storing the user data should be resumed or proceed to store another user data.

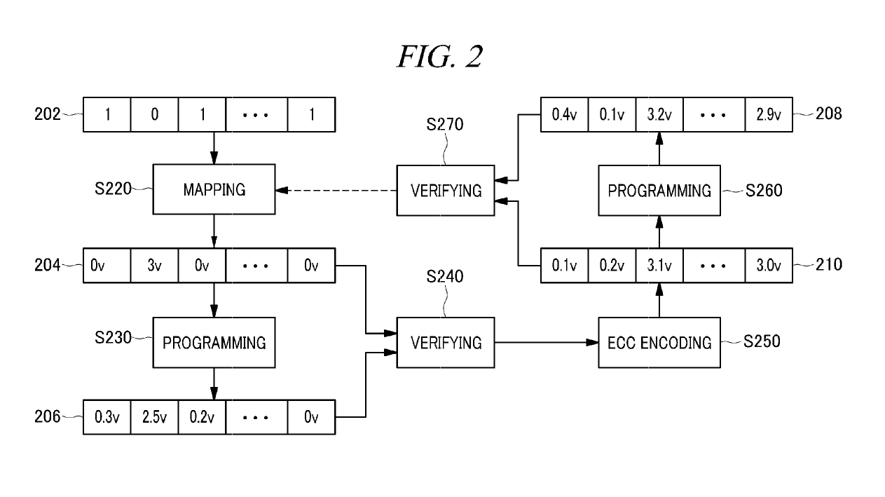

FIG. 2 shows an illustrative example operation flow to program data in a storage device using an ECC encoding method, arranged in accordance with at least some embodiments described herein. As illustrated in FIG. 2, controller 110 may store user data 202 as first analog values in a first group of memory cells in array 130. In storing the user data in the memory cells, controller 110 may perform an operation S220 of mapping the user data to reference threshold voltages as first analog values 204. Further, controller 110 may perform an operation S230 of programming the mapped reference threshold voltages to the first group of memory cells.

Further, controller 110 may perform an operation S240 of verifying the stored user data by reading second analog values 206 from the first group of memory cells in which the user data were stored. In reading second analog values 206, controller 110 may determine (or measure) the programmed reference threshold voltages from the first group of memory cells as second analog values 206. Then, a first distortion representative of a difference between first analog values 204 and second analog values 206 may be determined (or calculated).

If the first distortion is greater than a first threshold (or tolerance), controller 110 may determine that programming the user data fails, and resume storing the user data in array 130 by determining another group of memory cells in array 130 to store the user data. On the other hand, if the first distortion is less than or equal to the first threshold, controller 110 may perform an operation S250 of encoding second analog values 206 and/or the first distortion by use of an ECC to generate third analog values 210. In some embodiments, in encoding second analog values 206 and/or the first distortion, controller 110 may generate parity values using second analog values 206 and/or the first distortion. Controller 110 may then perform an operation S260 of programming third analog values 210 in a second group of memory cells in array 130.

In some embodiments, controller 110 may perform an operation S270 of verifying the encoded data stored in array 130 by reading fourth analog values 208 from the second group of memory cells in which the encoded data was stored. In reading fourth analog values 208, controller 110 may measure third analog values 210 from the second group of memory cells as fourth analog values 208. Controller 110 may then determine a second distortion representative of a difference between third analog values 210 and fourth analog values 208. If the second distortion is greater than a second threshold, controller 110 may determine that programming the encoded second analog values fails, and resume storing the user data in array 130 by determining another group of memory cells in array 130 to store the user data. On the other hand, if the second distortion is less than or equal to the second threshold, controller 110 may end the process of storing the user data and/or proceed to store another user data in array 130 of memory cells.

According to the above embodiments, the programmed threshold voltage and/or a distortion representing a difference (or actual program error) between the original user data and the programmed threshold voltages may be encoded, e.g., by use of an ECC, and stored in storage device 100. As a result, the program error that may have actually occurred in writing/reading the user data to/from storage device 100 can be incorporated in encoding the user data. Such information on the program error may be utilized in decoding the encoded user data and correcting any errors or distortion associated with the user data. Thus, according to the above embodiments, the robustness of the stored data for any future errors can be improved.

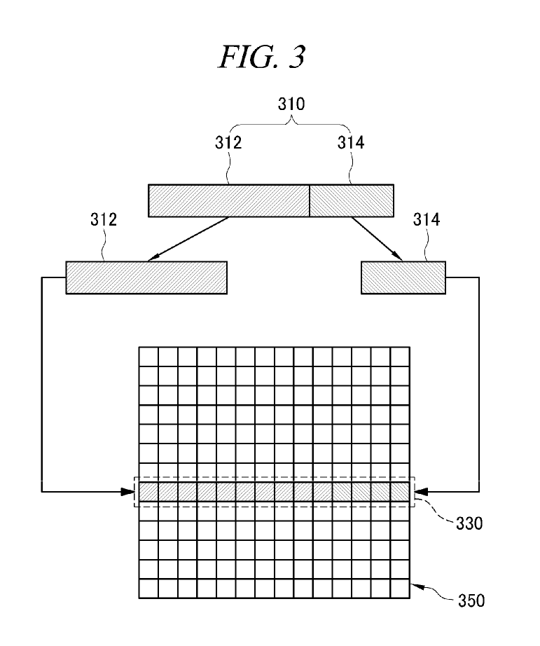

FIG. 3 shows an illustrative example array of memory cells where an encoded codeword including user data and parity values may be stored. As depicted, an encoded codeword 310 may include user data 312 along with parity values 314, which may be encoded based on reference threshold voltages programmed in accordance with user data 312 and/or a distortion indicating a difference between user data 312 and the programmed reference threshold voltages. Codeword 310 may be encoded in such a manner as described above with respect to FIGS. 1 and 2.

In some embodiments, encoded codeword 310 may be stored or programmed as a page 330 located in a row of memory cells in an array 350. Array 350 of memory cells may be configured in a similar manner to array 130 of memory cells described above with respect to FIGS. 1 and 2. More specifically, user data 312 may be programmed in a first portion of page 330. Further, programmed user data 312 may be verified to determine whether to proceed with an operation of encoding the programmed reference threshold voltages and/or a distortion associated with programmed user data 312 and storing the encoded data. If programmed user data 312 is verified, the programmed reference threshold voltages and/or the distortion may be encoded and programmed in a second portion of page 330.

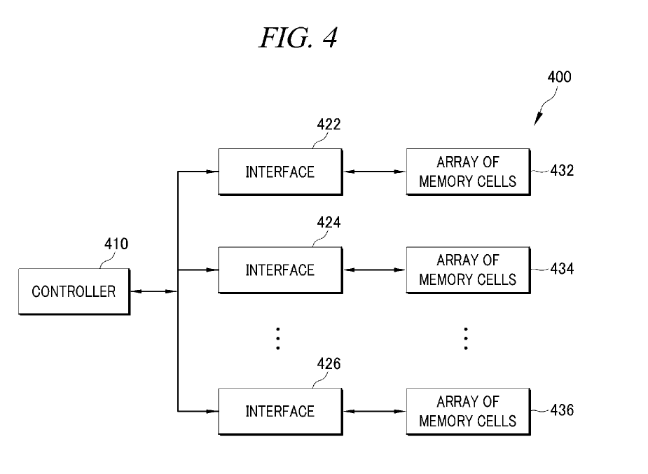

FIG. 4 shows a block diagram of an illustrative example storage device including a plurality of arrays of memory cells, arranged in accordance with at least some embodiments described herein. As depicted, a storage device 400 may include one or more of a controller 410, a plurality of interfaces 422, 424 and 426 and/or a plurality of arrays 432, 434 and 436 of memory cells. Interfaces 422 to 426 may operate under control/instructions of controller 410 to transfer data between one or more of arrays 432 to 436 and a host device (not shown).

In some embodiments, controller 410 may be any suitable type of processor unit such as a programmable microcontroller or other device similar to those described above with respect to controller 110. Each of arrays 432 to 436 may be any suitable type of memory device, such as a flash memory device or an SSD, including an array of nonvolatile analog memory cells. Also, arrays 432 to 436 may include any type of analog memory cells, such as NAND or NOR flash cells, PCM, NROM, FRAM, MRAM, DRAM, or other type of memory cells. Also, each of arrays 432 to 436 may be configured and operable in a similar manner to array 130 of memory cells as describe above with respect to FIGS. 1 and 2.

In some embodiments, storage device 400 may reduce the probability of making erroneous decisions as to the data content of memory cells in arrays 432 to 436 by encoding measured reference threshold voltages and/or a distortion that may occur in storing data in the cells using an ECC. Various types of error correcting codes may be used to encode a distortion. For example, the ECC may include a block code that separately encodes fixed-size blocks of data, including but not limited to the BCH code or the RS code.

In operation, controller 410 may be configured to communicate with at least one of arrays 432 to 436 of memory cells via at least one of interfaces 422 to 426. Controller 410 may access arrays 432 to 436 in a sequential manner or in a parallel manner or other manner or combination thereof. In some embodiments, controller 410 may perform pipeline programming and/or verifying operations upon arrays 432 to 436 of memory cells. More specifically, controller 410 may receive first user data from the host computer and store or program the first user data in a first group of memory cells (e.g., a page) in at least one of arrays 432 to 436. Then, controller 410 may verify the stored first user data by determining whether a first distortion occurring in programming the first user data (or program error) is within a first tolerance. If the program error is less than the first tolerance, controller 410 may encode the programmed first user data and/or first distortion, e.g., by generating parity values based on the programmed first user data and/or first distortion. The encoded data may be stored along with the first user data in another group of memory cells in at least one of arrays 432 to 436. The encoded data may be verified to determine whether storing the first user data should be resumed or proceed to store another user data.

In the meantime, controller 410 may receive second user data from the host computer and store or program the second user data in a second group of memory cells in at least one of arrays 432 to 436. The operation of storing the second user data may be performed during at least one of the operation of verifying the first distortion, the operation of encoding the programmed first user data and/or the first distortion, and the operation of storing the encoded data to carry out a pipeline programming operation upon more than one group of memory cells in arrays 432 to 436.

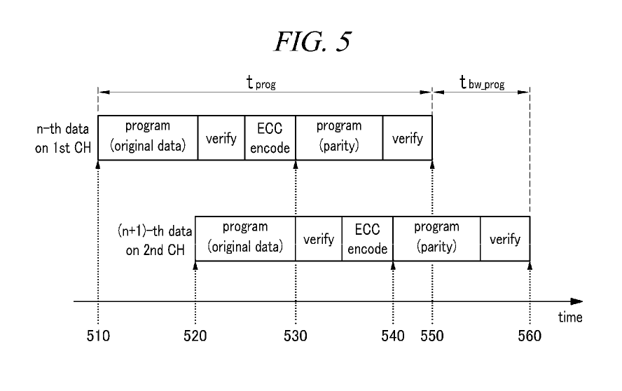

FIG. 5 shows a timing graph of an illustrative example pipeline operation to program data in a plurality of arrays of memory cells, arranged in accordance with at least some embodiments described herein. As depicted, programming n-th user data may start at a time 510 on a first channel, which may include interface 422 coupled to array 432 of memory cells. Also, programming (n+1)-th user data may start at a time 520 on a second channel, which may include interface 424 coupled to array 434 of memory cells. Time 520 may be delayed by a predetermined time (e.g., t_{bw}_{_}_{prog} as shown in FIG. 5) from time 510. In the meantime, verifying the programmed n-th user data and encoding the programmed n-th user data and/or a first distortion associated with the n-th user data may be performed during the operation of programming the (n+1)-th user data to generate a first encoded data.

Further, programming the first encoded data may start at a time 530 on the first channel. In the meantime, verifying the programmed (n+1)-th user data and encoding the programmed (n+1)-th user data and/or a second distortion associated with the (n+1)-th user data may be performed during the operation of programming the first encoded data to generate a second encoded data. Again, programming the second encoded data may start at a time 540 on the second channel. In the meantime, verifying the programmed first encoded data may be performed during the operation of programming the second encoded data.

In some embodiments, a storage device such as storage device 100 or storage device 400 (or a controller such as controller 110 or controller 410) may perform pipeline operations on a plurality of channels, e.g., including interfaces 422 to 426 coupled to arrays 432 to 436 of memory cells, in such a manner as described above with respect to FIG. 5. Although the pipeline operations are described above for the two channels, such pipeline operations may be similarly performed on more than two channels. Because multiple operations of storing data are performed on multiple channels in a pipelined manner, the overall performance of the storage device can be significantly improved compared to a storage device performing sequential operations of storing data on a single channel. For example, when performing 100 data storing operations, it may take (100*T_{prog}) for a storage device that performs sequential operations on a single channel, while it may take (T_{prog}+99*t_{bw}_{_}_{prog}) for a storage device that performs pipeline operations on multiple channels as illustrated in FIG. 5.

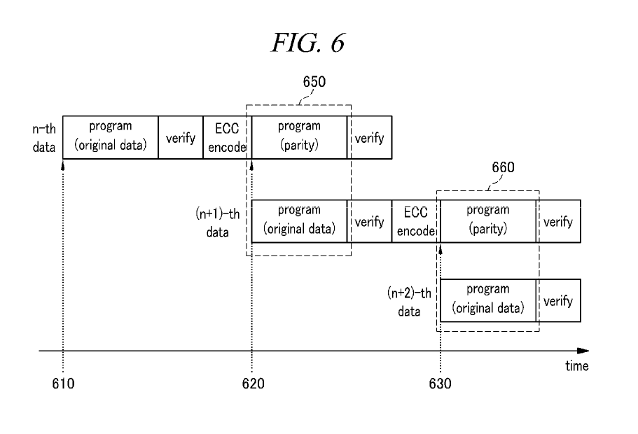

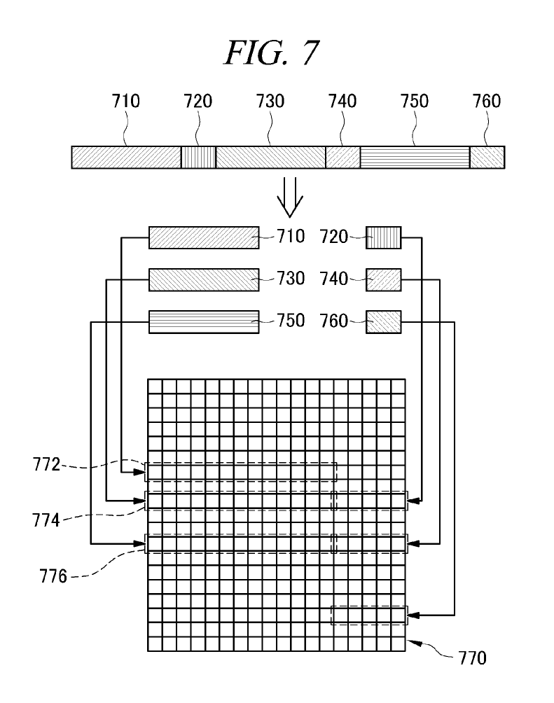

FIG. 6 shows a timing graph of another illustrative example pipeline operation to program data in a plurality of pages in an array of memory cells, arranged in accordance with at least some embodiments described herein. Also, FIG. 7 shows another illustrative example array of memory cells where an encoded codeword including user data and parity data may be stored, arranged in accordance with at least some embodiments described herein. The configuration of the array of memory cells as shown in FIG. 7 may be used for performing the pipeline operations of programming data as illustrated in FIG. 6, which will be described in more detail below.

As depicted in FIGS. 6 and 7, programming n-th user data 710 may start at a time 610 on a first page 772 in an array 770 of memory cells. Then, verifying programmed n-th user data 710 and encoding programmed n-th user data 710 and/or a first distortion associated with n-th user data 710 may be performed to generate a first encoded data 720, which may be followed by programming first encoded data 720 in a second page 774 which may be located separated from first page 772 in array 770 of memory cells. In the meantime, programming (n+1)-th user data 730 may start at a time 620. Programming (n+1)-th user data 730 may be performed in second page 774 in which first encoded data 720 is being programmed.

Similarly, verifying programmed the (n+1)-th user data 730 and encoding programmed the (n+1)-th user data 730 and/or a second distortion associated with (n+1)-th user data 730 may be performed to generate a second encoded data 740, which may be followed by programming second encoded data 740 in a third page 776 which may be located separated from first and second pages 772 and 774 in array 770 of memory cells. In the mean time, programming (n+2)-th user data 750 may start at a time 630. Programming (n+2)-th user data 750 may be performed in third page 776 in which second encoded data 740 is being programmed.

According to the above embodiment, programming encoded data associated with the n-th user data may be performed substantially at the same time (or at the same operation cycle) as programming the (n+1)-th user data. As a result, multiple operations of storing data may be performed on multiple pages in a pipelined manner, and thus, the overall performance of the storage device can be improved compared to sequential operations of storing data on a single page. Also, because a page including the (n+1)-th user data along with the encoded data associated with the n-th user data can be read together, an erroneous reading of data in the memory cells which may be caused by disturb noise can be reduced.

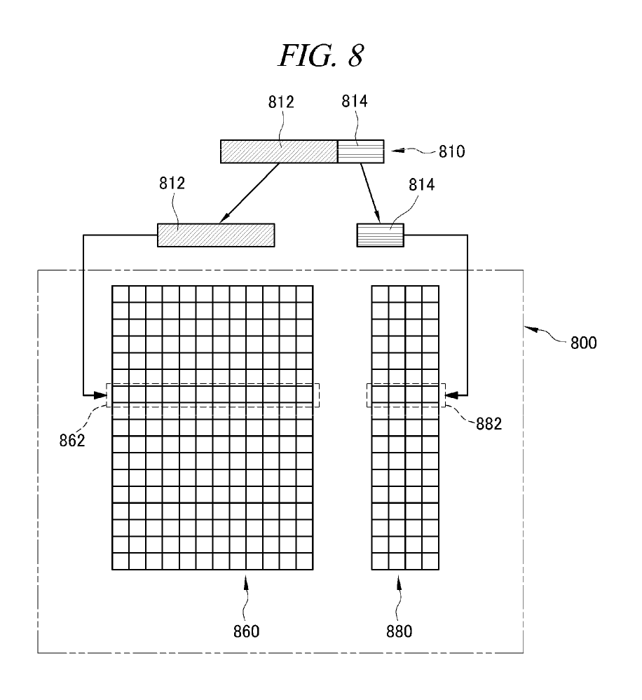

FIG. 8 shows yet another illustrative example array of memory cells where an encoded codeword including user data and parity data may be stored, arranged in accordance with at least some embodiments described herein. As depicted, an array 800 of memory cells may include a memory region 860 configured to store user data, and another memory region 880 configured to store encoded data (e.g., parity values). Although memory regions 860 and 880 are illustrated as being included in one array 800 of memory cells, memory regions 860 and 880 may be arranged in two separate arrays of memory cells, respectively. Memory region 880 may be arranged to be physically separated from memory region 860, such that some type of distortions (e.g., interference noise, disturb noise) caused by unintended interference between adjacent cells can be reduced.

As illustrated in FIG. 8, an encoded codeword 810 may include user data 812 along with parity values 814, which may be encoded based on reference threshold voltages programmed in accordance with user data 812 and/or a distortion indicating a difference between user data 812 and the programmed reference threshold voltages. Codeword 810 may be encoded in such a manner as described above with respect to FIGS. 1 and 2. User data 812 may be programmed in a page 862 in memory region 860, while parity values 814 may be programmed in a page 882 in memory region 880. Thus, read/write/erase operations on user data 812 stored in memory region 860 may not affect parity values 814 stored in memory region 880.

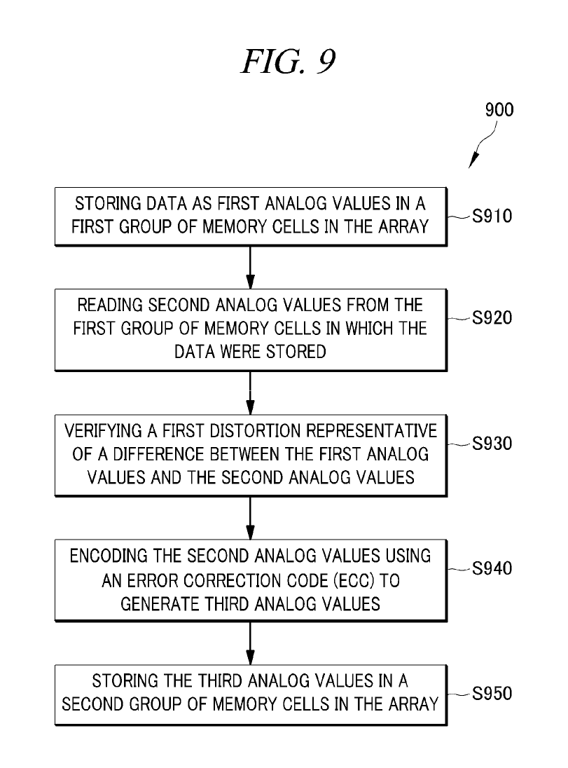

FIG. 9 illustrates an example flow diagram of a method adapted to store data in a storage device that includes an array of memory cells, arranged in accordance with at least some embodiments described herein. An example method 900 in FIG. 9 may be implemented using, for example, a computing device including a processor adapted to store or control storage of data in a storage device. In some embodiments, the storage device may include one or more arrays of memory cells.

Method 900 may include one or more operations, actions, or functions as illustrated by one or more of blocks S910, S920, S930, S940 and/or S950. Although illustrated as discrete blocks, various blocks may be divided into additional blocks, combined into fewer blocks, supplemented with other blocks, or eliminated, depending on the particular implementation. In some further examples, the various described blocks may be implemented as a parallel process instead of a sequential process, or as a combination thereof. Method 900 may begin at block S910, “STORING DATA AS FIRST ANALOG VALUES IN A FIRST GROUP OF MEMORY CELLS IN THE ARRAY.”

At block S910, data may be stored data as first analog values in a first group of memory cells in the array. As depicted in FIGS. 1 and 2, controller 110 may store user data 202 as first analog values in a first group of memory cells in array 130. In storing the data in the memory cells, controller 110 may perform an operation S220 of mapping the data to reference threshold voltages as first analog values 204. Further, controller 110 may perform an operation S230 of programming the mapped reference threshold voltages to the first group of memory cells. Block S910 may be followed by block S920, “READING SECOND ANALOG VALUES FROM THE FIRST GROUP OF MEMORY CELLS IN WHICH THE DATA WERE STORED.”

At block S920, second analog values may be read from the first group of memory cells in which the data were stored. As illustrated in FIGS. 1 and 2, second analog values 206 may be read from the first group of memory cells in which the data were stored. In reading second analog values 206, controller 110 may determine (or measure) the programmed reference threshold voltages from the first group of memory cells as second analog values 206. Block S920 may be followed by block S930, “VERIFYING A FIRST DISTORTION REPRESENTATIVE OF A DIFFERENCE BETWEEN THE FIRST ANALOG VALUES AND THE SECOND ANALOG VALUES.”

At block S930, a first distortion representative of a difference between the first analog values and the second analog values may be verified. As illustrated in FIGS. 1 and 2, controller 110 may perform an operation S240 of verifying the stored user data. Then, a first distortion representative of a difference between first analog values 204 and second analog values 206 are determined (or calculated). If the first distortion is greater than a first threshold (or tolerance), controller 110 may determine that programming the user data fails, and resume storing the user data in array 130 by determining another group of memory cells in array 130 to store the user data. On the other hand, if the first distortion is less than or equal to the first threshold, controller 110 may perform an operation S250 of encoding the second analog values by use of an ECC to generate third analog values. Block S930 may be followed by block S940, “ENCODING THE SECOND ANALOG VALUES USING AN ERROR CORRECTION CODE (ECC) TO GENERATE THIRD ANALOG VALUES.”

At block S940, the second analog values may be encoded using an ECC. As illustrated in FIGS. 1 and 2, controller 110 may perform an operation S250 of encoding the second analog values by use of an ECC. In some embodiments, in encoding the second analog values, controller 110 may generate parity values using the second analog values and/or the first distortion. Various types of error correcting codes known in the art may be used to encode the second analog values. For example, the ECC may include a block code that separately encodes fixed-size blocks of data, including but not limited to the BCH code or the RS code. Block S940 may be followed by block S950, “STORING THE THIRD ANALOG VALUES IN A SECOND GROUP OF MEMORY CELLS IN THE ARRAY.”

At block S950, the third analog values may be stored in a second group of memory cells in the array. As illustrated in FIGS. 1 and 2, controller 110 may perform an operation S260 of programming third analog values 210 in a second group of memory cells in array 130.

In some embodiments, the third analog values stored in the array may be verified by reading fourth analog values from the second group of memory cells in which the third analog values were stored. As illustrated in FIGS. 1 and 2, in reading fourth analog values 208, controller 110 may measure third analog values 210 from the second group of memory cells as fourth analog values 208. Controller 110 may then determine a second distortion representative of a difference between third analog values 210 and fourth analog values 208. If the second distortion is greater than a second threshold, controller 110 may determine that programming the encoded second analog values fails, and resume storing the user data in array 130 by determining another group of memory cells in array 130 to store the user data. On the other hand, if the second distortion is less than or equal to the second threshold, controller 110 may end the process of storing the user data and/or proceed to store another user data in array 130 of memory cells.

For this and other methods disclosed herein, the functions or operations performed in the methods may be implemented in differing order. Furthermore, the outlined operations are only provided as examples, and some of the operations may be optional, combined into fewer operations, supplemented with other operations, or expanded into additional operations without detracting from the essence of the disclosed embodiments.

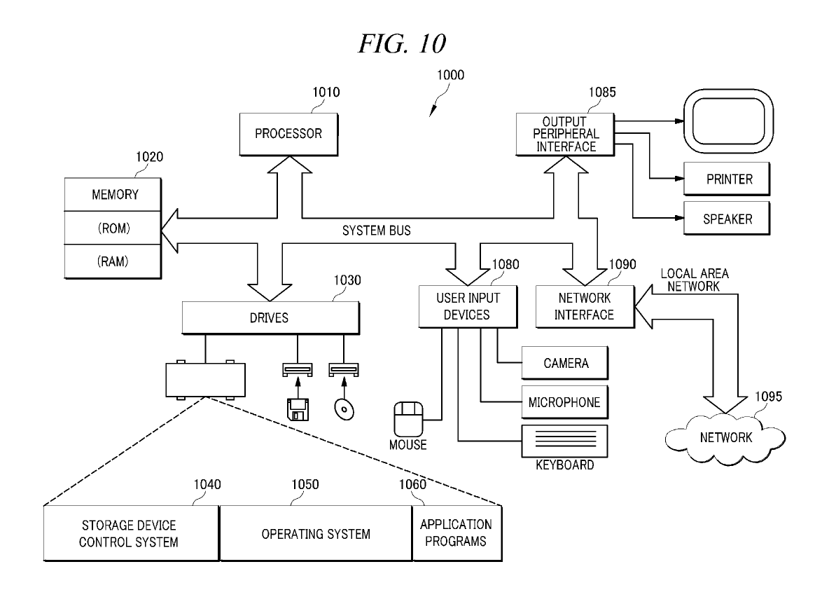

FIG. 10 shows a block diagram of an example computing system that can be configured to implement methods to store data in a storage device that includes an array of memory cells, arranged in accordance with at least some embodiments described herein. As depicted in FIG. 10, a computer 1000 may include a processor 1010, a memory 1020 and one or more drives 1030. Computer 1000 may be implemented as a computer system, an embedded control computer, a laptop, or a server computer, a mobile device, a set-top box, a kiosk, a vehicular information system, a mobile telephone, a customized machine, or other hardware platform.

Drives 1030 and their associated computer storage media may provide storage of computer readable instructions, data structures, program modules and other data for computer 1000. Drives 1030 may include a storage device control system 1040, an operating system (OS) 1050, and application programs 1060. Storage device control system 1040 may be adapted to store data in such a manner as described above with respect to FIGS. 1 to 9. In some embodiments, the controller(s) previous described above (such as controller 110) may be implemented by processor 1010, and the array(s) of memory cells (such as array 130) may be implemented by memory 1020. Further in some embodiments, storage device control system 1040 may implement the interface(s) described above (such as interface 120), and in some instances may include processor 1010.

Computer 1000 may further include user input devices 1080 through which a user may enter commands and data. Input devices can include an electronic digitizer, a camera, a microphone, a keyboard and pointing device, commonly referred to as a mouse, trackball or touch pad. Other input devices may include a joystick, game pad, satellite dish, scanner, or the like.

These and other input devices can be coupled to processor 1010 through a user input interface that is coupled to a system bus, but may be coupled by other interface and bus structures, such as a parallel port, game port or a universal serial bus (USB). Computers such as computer 1000 may also include other peripheral output devices such as display devices, which may be coupled through an output peripheral interface 1085 or the like.

Computer 1000 may operate in a networked environment using logical connections to one or more computers, such as a remote computer coupled to a network interface 1090. The remote computer may be a personal computer, a server, a router, a network PC, a peer device or other common network node, and can include many or all of the elements described above relative to computer 1000.

Networking environments are commonplace in offices, enterprise-wide area networks (WAN), local area networks (LAN), intranets, and the Internet. When used in a LAN or WLAN networking environment, computer 1000 may be coupled to the LAN through network interface 1090 or an adapter. When used in a WAN networking environment, computer 1000 typically includes a modem or other means for establishing communications over the WAN, such as the Internet or a network 1095. The WAN may include the Internet, the illustrated network 1095, various other networks, or any combination thereof. Other mechanisms of establishing a communications link, ring, mesh, bus, cloud, or network between the computers may be used.

In some embodiments, computer 1000 may be coupled to a networking environment. Computer 1000 may include one or more instances of a physical computer-readable storage medium or media associated with drives 1030 or other storage devices. The system bus may enable processor 1010 to read code and/or data to/from the computer-readable storage media. The media may represent an apparatus in the form of storage elements that are implemented using any suitable technology, including but not limited to semiconductors, magnetic materials, optical media, electrical storage, electrochemical storage, or any other such storage technology. The media may represent components associated with memory 1020, whether characterized as RAM, ROM, flash, or other types of volatile or nonvolatile memory technology. The media may also represent secondary storage, whether implemented as storage drives 1030 or otherwise. Hard drive implementations may be characterized as solid state, or may include rotating media storing magnetically encoded information.

Processor 1010 may be constructed from any number of transistors or other circuit elements, which may individually or collectively assume any number of states. More specifically, processor 1010 may operate as a state machine or finite-state machine. Such a machine may be transformed to a second machine, or specific machine by loading executable instructions. These computer-executable instructions may transform processor 1010 by specifying how processor 1010 transitions between states, thereby transforming the transistors or other circuit elements constituting processor 1010 from a first machine to a second machine. The states of either machine may also be transformed by receiving input from user input devices 1080, network interface 1090, other peripherals, other interfaces, or one or more users or other actors. Either machine may also transform states, or various physical characteristics of various output devices such as printers, speakers, video displays, or otherwise.

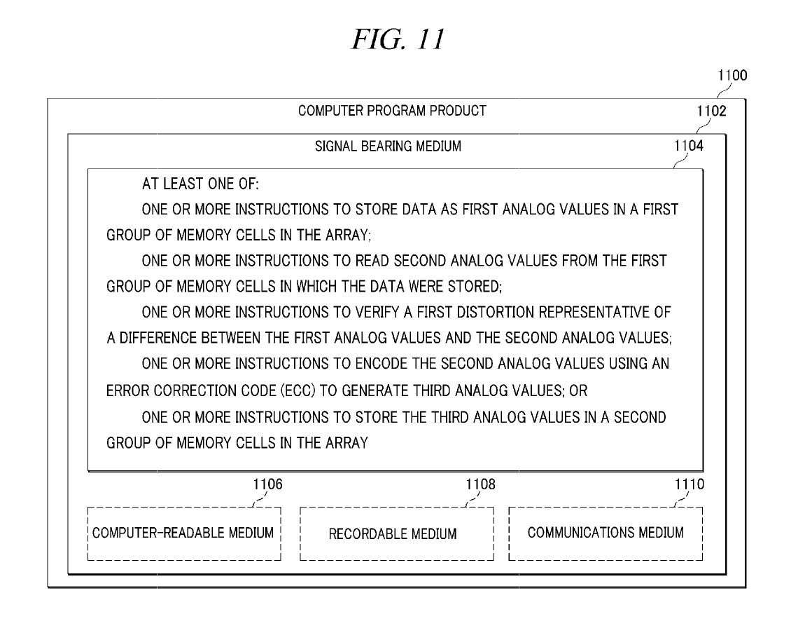

FIG. 11 illustrates a computer program product that can be utilized to store data in a storage device that includes an array of memory cells, arranged in accordance with at least some embodiments described herein. Program product 1100 may include a signal bearing medium 1102. Signal bearing medium 1102 may include one or more instructions 1104 that, in response to execution by, for example, a processor or a storage device, may provide the functionality and features described above with respect to FIGS. 1 to 10. In some embodiments, the storage device may include one or more of an interface operable to communicate with one or more arrays of memory cells. By way of example, instructions 1104 may include at least one of: one or more instructions to store data as first analog values in a first group of memory cells in the array; one or more instructions to read second analog values from the first group of memory cells in which the data were stored; one or more instructions to verify a first distortion representative of a difference between the first analog values and the second analog values; one or more instructions to encode the second analog values using an error correction code (ECC) to generate third analog values; or one or more instructions to store the third analog values in a second group of memory cells in the array. Thus, for example, referring to FIGS. 1 to 8, storage device 100 or 400 may undertake one or more of the blocks shown in FIG. 9 in response to instructions 1104.

In some implementations, signal bearing medium 1102 may encompass a non-transitory computer-readable medium 1106, such as, but not limited to, a hard disk drive, a Compact Disc (CD), a Digital Video Disk (DVD), a digital tape, memory, etc. In some implementations, signal bearing medium 1102 may encompass a recordable medium 1108, such as, but not limited to, memory, read/write (R/W) CDs, R/W DVDs, etc. In some implementations, signal bearing medium 1102 may encompass a communications medium 1110, such as, but not limited to, a digital and/or an analog communication medium (e.g., a fiber optic cable, a waveguide, a wired communications link, a wireless communication link, etc.). Thus, for example, program product 1100 may be conveyed to one or more modules of storage device 100 or 400 by an RF signal bearing medium 1102, where the signal bearing medium 1102 is conveyed by a wireless communications medium 1110 (e.g., a wireless communications medium conforming with the IEEE 802.11 standard).

The present disclosure is not to be limited in terms of the particular embodiments described in this application, which are intended as illustrations of various aspects. Many modifications and variations may be made without departing from its spirit and scope. Functionally equivalent methods and apparatuses within the scope of the disclosure, in addition to those enumerated herein, are possible from the foregoing descriptions. Such modifications and variations are intended to fall within the scope of the appended claims. The present disclosure is to be limited only by the terms of the appended claims, along with the full scope of equivalents to which such claims are entitled. This disclosure is not limited to particular methods, reagents, compounds, compositions or biological systems, which can, of course, vary. The terminology used herein is for the purpose of describing particular embodiments only, and is not intended to be limiting.

The herein described subject matter sometimes illustrates different components contained within, or connected with, different other components. Such depicted architectures are merely examples, and in fact, many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member.

From the foregoing, various embodiments of the present disclosure have been described herein for purposes of illustration, and various modifications may be made without departing from the scope and spirit of the present disclosure. Accordingly, the various embodiments disclosed herein are not intended to be limiting, with the true scope and spirit being indicated by the following claims.

1. A method to store data in a storage device that includes an array of analog memory cells, the method comprising:
storing data as first analog values in a first group of memory cells in the array;
reading second analog values from the first group of memory cells in which the data were stored;
verifying a first distortion representative of a difference between the first analog values and the second analog values;
encoding the second analog values using an error correction code (ECC) to generate third analog values;
storing the third analog values in a second group of memory cells in the array;
reading fourth analog values from the second group of memory cells in which the third analog values were stored; and
verifying a second distortion representative of a difference between the third analog values and the fourth analog values.

2. The method of claim 1, wherein storing the data comprises:
mapping the data to reference threshold voltages as the first analog values; and
programming the mapped reference threshold voltages to the first group of memory cells.

3. The method of claim 2, wherein reading the second analog values comprises measuring the programmed reference threshold voltages from the first group of memory cells as the second analog values.

4. The method of claim 1, wherein encoding the second analog values comprises generating an ECC parity as the third analog values.

5. The method of claim 1, wherein encoding the second analog values comprises encoding the second analog values using a block code comprising at least one of a Bose-Chaudhuri-Hochquenghem (BCH) code and a Reed-Solomon (RS) code.

6. (canceled)

7. The method of claim 1, wherein verifying the second distortion comprises:
comparing the second distortion with a threshold value; and
in response to determination that the second distortion is greater than the threshold value, performing:
storing the data as fifth analog values in a third group of memory cells in the array;
reading sixth analog values from the third group of memory cells in which the data were stored;
verifying a third distortion representative of a difference between the fifth analog values and the sixth analog values;
encoding the sixth analog values using the ECC to generate seventh analog values; and
storing the seventh analog values in a fourth group of memory cells in the array.

8. A storage device, comprising:
an interface configured to communicate with an array of analog memory cells; and
a processor coupled to the interface, wherein the processor is configured to perform or cause to be performed:
store, via the interface, data as first analog values in a first group of memory cells in the array;
read, via the interface, second analog values from the first group of memory cells in which the data were stored;
verify a first distortion representative of a difference between the first analog values and the second analog values;
encode the second analog values by use of an error correction code (ECC) to generate third analog values;
store, via the interface, the third analog values in a second group of memory cells in the array;
read, via the interface, fourth analog values from the second group of memory cells in which the third analog values were stored; and
verify a second distortion representative of a difference between the third analog values and the fourth analog values.

9. The storage device of claim 8, wherein the processor is further configured to perform or cause to be performed:
map the data to reference threshold voltages as the first analog values; and
program the mapped reference threshold voltages to the first group of memory cells.

10. The storage device of claim 9, wherein the processor is further configured to perform or cause to be performed:
determine the programmed reference threshold voltages from the first group of memory cells as the second analog values.

11. The storage device of claim 8, wherein the processor is further configured to perform or cause to be performed:
generate an ECC parity as the third analog values.

12. The storage device of claim 8, wherein the ECC comprises a block code.

13. The storage device of claim 12, wherein the block code comprises at least one of a Bose-Chaudhuri-Hochquenghem (BCH) code and a Reed-Solomon (RS) code.

14. (canceled)

15. The storage device of claim 1, wherein the processor is further configured to perform or cause to be performed:
verify the second distortion by comparison of the second distortion with a threshold value; and
in response to determination that the second distortion is greater than the threshold value:
store, via the interface, the data as fifth analog values in a third group of memory cells in the array;
read, via the interface, sixth analog values from the third group of memory cells in which the data were stored;
verify a third distortion representative of a difference between the fifth analog values and the sixth analog values;
encode the sixth analog values using the ECC to generate seventh analog values; and
store, via the interface, the seventh analog values in a fourth group of memory cells in the array.

16. The storage device of claim 8, wherein the analog memory cells are selected from memory cell types comprising one or more of flash memory cells, dynamic random access memory (DRAM) cells, phase change memory (PCM) cells, nitride read-only memory (NROM) cells, magnetoresistive random access memory (MRAM) cells, and ferroelectric random access memory (FRAM) cells.

17. (canceled)

18. A storage device, comprising:
a first interface configured to communicate with a first array of analog memory cells;
a second interface configured to communicate with a second array of analog memory cells; and
a processor coupled to the first interface and the second interface, wherein the processor is configured to perform or cause to be performed:
store, via the first interface, first data as first analog values in a first group of memory cells in the first array;
read, via the first interface, second analog values from the first group of memory cells in which the first data were stored;
verify a first distortion representative of a difference between the first analog values and the second analog values;
encode the second analog values, by use of an error correction code (ECC) to generate third analog values;
store, via the first interface, the third analog values in a second group of memory cells in the first array, wherein the processor is further configured to perform or cause to be performed:
store, via the second interface, second data as other analog values in a group of memory cells in the second array during at least one of the read of the second analog values, the verification of the first distortion, the encode of the second analog values, and the storage of the third analog values to carry out a pipeline program operation upon the first and second arrays of analog memory cells.

19. The storage device of claim 18, wherein the processor is further configured to perform or cause to be performed:
map the first data to reference threshold voltages as the first analog values; and
program the mapped reference threshold voltages to the first group of memory cells.

20. The storage device of claim 19, wherein the processor is further configured to perform or cause to be performed:
determine the programmed reference threshold voltages from the first group of memory cells as the second analog values.

21. The storage device of claim 18, wherein the processor is further configured to perform or cause to be performed:
generate an ECC parity as the third analog values.

22. The storage device of claim 18, wherein the ECC comprises a block code.

23. The storage device of claim 22, wherein the block code comprises at least one of a Bose-Chaudhuri-Hochquenghem (BCH) code and a Reed-Solomon (RS) code.

24. The storage device of claim 18, wherein the processor is further configured to perform or cause to be performed:
read, via the first interface, fourth analog values from the second group of memory cells in which the third analog values were stored; and
verify a second distortion representative of a difference between the third analog values and the fourth analog values.

25. The storage device of claim 24, wherein the processor is further configured to perform or cause to be performed:
verify the second distortion by comparison of the second distortion with a threshold value; and
in response to determination that the second distortion is greater than the threshold value:
store, via the first interface, the second data as fifth analog values in a third group of memory cells in the first array;
read, via the first interface, sixth analog values from the third group of memory cells in which the second data were stored;
verify a third distortion representative of a difference between the fifth analog values and the sixth analog values;
encode the sixth analog values using the ECC to generate seventh analog values; and
store, via the first interface, the seventh analog values in a fourth group of memory cells in the first array.

26. The storage device of claim 18, wherein the analog memory cells are selected from memory cell types comprising one or more of flash memory cells, dynamic random access memory (DRAM) cells, phase change memory (PCM) cells, nitride read-only memory (NROM) cells, magnetoresistive random access memory (MRAM) cells, and ferroelectric random access memory (FRAM) cells.
